(19) United States
(12) Patent Application Publication
(10) Pub. No.: US 2023/0287561 A1
(43) Pub. Date: Sep. 14, 2023

(54) Variable Rotation Rate Batch Implanter

(71) Applicant: Applied Materials, Inc., Santa Clara, CA (US)

(72) Inventors: Stanislav S. Todorov, Topsfield, MA (US); Robert J. Mitchell, Winchester, MA (US); Joseph C. Olson, Beverly, MA (US); Frank Sinclair, Hartland, ME (US)

(21) Appl. No.: 17/694,028

(22) Filed: Mar. 14, 2022

(51) Int. Cl. C23C 14/48; C23C 14/50

(52) U.S. Cl. CPC C23C 14/48; C23C 14/505

(57) ABSTRACT

A system comprising a spinning disk is disclosed. The system comprises a semiconductor processing system, such as a high energy implantation system. The semiconductor processing system produces a spot ion beam, which is directed to a plurality of workpieces, which are disposed on the spinning disk. The spinning disk comprises a rotating central hub with a plurality of platens. The spinning disk rotates about a central axis. The spinning disk is also translated linearly in a directional perpendicular to the central axis. The spot ion beam strikes the spinning disk at a distance from the central axis, referred to as the radius of impact. The rotation rate and the scan velocity may both vary inversely with the radius of impact.

### FIELD

Embodiments of this disclosure are directed to systems and methods for processing workpieces using a batch implanter that includes a spinning disk.

### BACKGROUND

High energy implantation systems are used to create semiconductor devices that have deep implanted regions. One specific type of device is referred to as an insulated gate bipolar transistor (IGBT). An IGBT combines concepts from bipolar transistors and MOSFETs to achieve an improved power device. The emitter and the gate are disposed on one side of the device, while the collector is disposed on the opposite second side of the device. The emitter is in communication with a heavily p-doped region disposed directly below the emitter. On either side of the heavily p-doped region are heavily n-doped regions, each in communication with the gate. Beneath the heavily p-doped region is a lightly p-doped region. On the opposite side of the device is a second heavily p-doped region, in communication with the collector. Finally, between the second heavily p-doped region and the lightly p-doped region is a lightly n-doped drift layer.

In some embodiments, high energy implants may be used to create these devices. Traditionally, in these implantation systems, a spot beam is generated, and the batch implanter, which includes a plurality of workpieces on a spinning disk, is scanned through the spot beam. The spinning disk rotates at a constant rotation rate, ω, while the spinning disk may be linearly translated at a scan velocity, v through the spot beam. Because the outer perimeter of the spinning disk has a larger radius than the inner perimeter, the dose implanted along the outer radius of the spinning disk will be lower than that along the inner radius. This is due to the fact that the outer radius has a larger surface area than the inner radius.

One way to compensate for this is vary the scan velocity inversely as a function of radius. This may allow a more uniform dose to be implanted. However, at slower rotation rates, this approach may result in non-uniformities in the radial direction.

Therefore, it would be beneficial if there were a semiconductor processing system that could perform high energy implants without the drawbacks of the present technologies. More particularly, it would be beneficial if there were a system that performs high energy implants on a batch of workpieces and achieves uniform dose in each of the workpieces.

### SUMMARY

A system comprising a spinning disk is disclosed. The system comprises a semiconductor processing system, such as a high energy implantation system. The semiconductor processing system produces a spot ion beam, which is directed to a plurality of workpieces, which are disposed on the spinning disk. The spinning disk comprises a rotating central hub with a plurality of platens. The spinning disk rotates about a central axis. The spinning disk is also translated linearly in a directional perpendicular to the central axis. The spot ion beam strikes the spinning disk at a distance from the central axis, referred to as the radius of impact. The rotation rate and the scan velocity may both vary inversely with the radius of impact.

According to one embodiment, a batch implanter is disclosed. The batch implanter comprises a spinning disk adapted to process a plurality of workpieces, comprising a central hub adapted to rotate about a central axis; a plurality of spokes extending radially outward from the central hub; a platen disposed on a distal end of each of the plurality of spokes; and a translating structure on which the spinning disk is mounted, wherein a spot ion beam is adapted to strike the spinning disk at a distance from the central axis, referred to as a radius of impact, and wherein a rotation rate of the spinning disk about the central axis decreases as the radius of impact increases. In some embodiments, the rotation rate varies inversely as the radius of impact. In certain embodiments, a maximum rotation rate of the spinning disk is between 30 and 1000 RPM. In some embodiments, the translating structure moves at a scan velocity, and the scan velocity decreases as the radius of impact increases. In certain embodiments, the scan velocity varies inversely as the radius of impact. In some embodiments, a maximum scan velocity is between 5 and 50 cm/sec.

According to another embodiment, an ion implantation system is disclosed. The ion implantation system comprises an ion source to generate ions; an accelerator to accelerate the ions and create a spot beam; and the batch implanter described above.

According to another embodiment, a batch implanter is disclosed. The batch implanter comprises a spinning disk adapted to process a plurality of workpieces, comprising a plurality of platens and a rotating motor to rotate the spinning disk about a central axis; a translating structure on which the spinning disk is mounted, wherein a spot ion beam is adapted to strike the spinning disk at a distance from the central axis, referred to as a radius of impact; an actuator configured to move the translating structure linearly at a scan velocity; and a controller, in communication with the rotating motor wherein the controller controls the rotating motor such that a rotation rate of the spinning disk about the central axis decreases as the radius of impact increases. In some embodiments, the controller controls the rotating motor such that the rotation rate varies inversely as the radius of impact. In certain embodiments, a maximum rotation rate of the spinning disk is between 30 and 1000 RPM. In some embodiments, the controller is in communication with the actuator and controls the actuator such that the scan velocity of the translating structure decreases as the radius of impact increases. In some embodiments, the scan velocity varies inversely with the radius of impact. In some embodiments, the translating structure moves linearly in a direction perpendicular to the central axis. In some embodiments, the batch implanter comprises one or more sensors in communication with the controller, wherein the controller determines the radius of impact based on information from the one or more sensors. In certain embodiments, the controller determines the radius of impact using a table or equation based on time.

According to another embodiment, an ion implantation system is disclosed. The ion implantation system comprises an ion source to generate ions; an accelerator to accelerate the ions and create a spot beam; and the batch implanter described above.

According to another embodiment, a batch implanter is disclosed. The batch implanter comprises a spinning disk adapted to process a plurality of workpieces, comprising a plurality of platens and a rotating motor to rotate the spinning disk about a central axis; and a translating structure on which the spinning disk is mounted, wherein the translating structure is configured to move at a scan velocity; wherein a spot ion beam is adapted to strike the spinning disk at a distance from the central axis, referred to as a radius of impact, and wherein a rotation rate of the spinning disk and the scan velocity vary as a function of the radius of impact, and wherein a ratio of the scan velocity to the rotation rate remains nearly constant as the translating structure moves. In some embodiments, the scan velocity and the rotation rate vary inversely with the radius of impact.

According to another embodiment, an ion implantation system is disclosed. The ion implantation system comprises an ion source to generate ions; an accelerator to accelerate the ions and create a spot beam; and the batch implanter described above.

### BRIEF DESCRIPTION OF THE FIGURES

For a better understanding of the present disclosure, reference is made to the accompanying drawings, which are incorporated herein by reference and in which:

FIG. 1A shows a semiconductor processing apparatus that may be utilized according to one embodiment;

FIG. 1B shows a semiconductor processing apparatus that may be utilized according to a second embodiment;

FIG. 2A shows a spinning disk according to one embodiment;

FIG. 2B shows a side view of the spinning disk of FIG. 2A;

FIGS. 3A-3B show the operation of the spinning disk and translating support;

FIG. 4 shows the path of a spot ion beam across the spinning disk, which is moving at a varying scan velocity and a varying rotation rate;

FIG. 5 shows the path of a spot ion beam across the spinning disk, which is moving at a varying scan velocity and a constant rotation rate; and

FIG. 6 shows the effects of large spacing between the convolutions of the spiral.

### DETAILED DESCRIPTION

The present disclosure describes the use of a spinning disk in conjunction with a semiconductor processing system to implant ions with high energy and low angular spread. There are various semiconductor processing systems that may be used with the spinning disk.

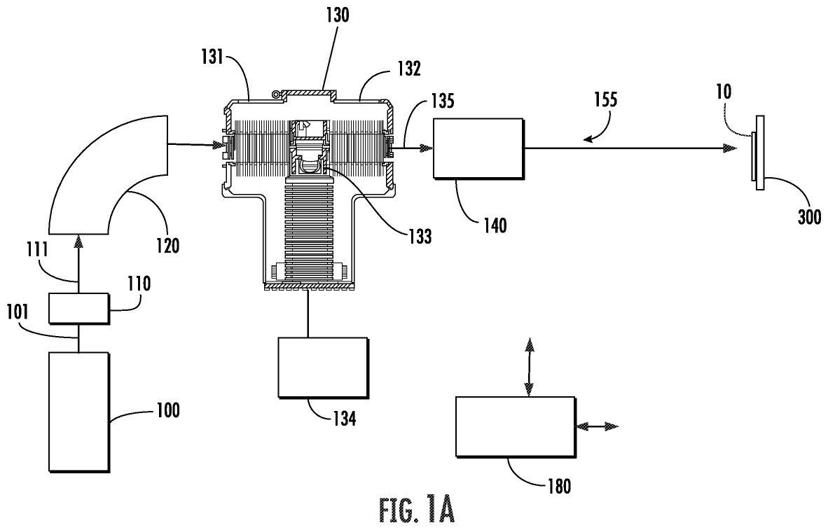

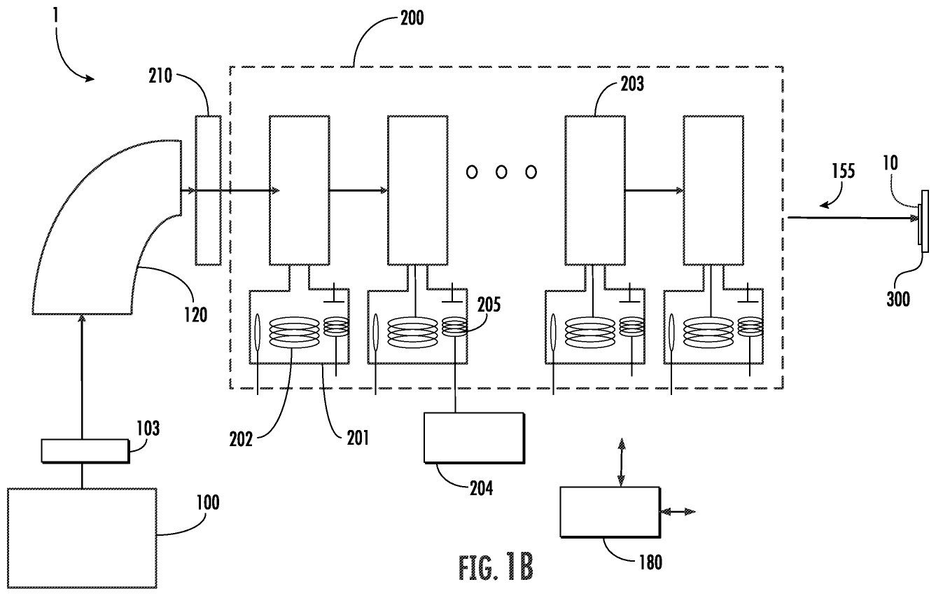

As shown in FIG. 1A, a semiconductor processing system comprises an ion source 100, which is used to generate an ion beam.

In one embodiment, a positive ion beam 101 may be created in the traditional manner, such as using a Bernas or indirectly heated cathode (IHC) ion source. Of course, other types of ion sources may also be employed. A feedgas is supplied to the ion source 100, which is then energized to generate ions. In certain embodiments, the feedgas may be hydrogen, boron, phosphorus, arsenic, helium, or other suitable species. Extraction optics are then used to extract these ions from the ion source 100.

The positive ion beam 101 exiting the ion source 100 may be coupled to a Mg charge exchange cell 110, which transforms the positive ion beam 101 into a negative ion beam 111. Of course, other mechanisms for the generation of a negative ion beam are known in the art. The mechanism used to create the negative ion beam is not limited by this disclosure.

The negative ion beam 111 may be directed toward a mass analyzer 120, which only allows the passage of certain species of ions. The negative ions that exit the mass analyzer 120 are directed toward a tandem accelerator 130.

The tandem accelerator 130 has two pathways, which are separated by a stripper tube 133. The input pathway 131 comprises a plurality of input electrodes. These input electrodes may be any suitable electrically conductive material, such as titanium or other metals. The outermost input electrode may be grounded. Each of the subsequent input electrodes may be biased at an increasingly more positive voltage moving closer to the stripper tube 133.

The input pathway 131 leads to the stripper tube 133. The stripper tube 133 is biased positively relative to the outermost input electrode. The stripper tube 133 includes an injection conduit where a stripper gas is injected. The stripper gas may comprise neutral molecules. These neutral molecules may be any suitable species such as, but not limited to argon and nitrogen. The stripper tube 133 has an inlet disposed on the same side as the input pathway 131. The outlet of the stripper tube 133 is in communication with the output pathway 132.

In other words, the stripper tube 133 is positively biased so as to attract the negative ion beam 111 through the input pathway 131. The stripper tube 133 removes electrons from the incoming ions, transforming them from negative ions into positive ions.

The stripper tube 133 is more positive than the electrodes in the output pathway 132. Each subsequent output electrode may be less positively biased moving away from the stripper tube 133. For example, the outermost output electrode may be grounded. Thus, the positive ions in the stripper tube 133 are accelerated through the output pathway 132.

In this way, the ions are accelerated two times. First, negative ions are accelerated through the input pathway 131 to the stripper tube 133. This acceleration is based on the difference between the voltage of the outermost input electrode and the voltage of the stripper tube 133. Next, positive ions are accelerated through the output pathway 132. This acceleration is based on the difference between the voltage of the stripper tube 133 and the voltage of the outermost output electrode in the output pathway 132.

An accelerator power supply 134 may be used to supply the voltages to the stripper tube 133, as well as the electrodes in the input pathway 131 and the output pathway 132. The accelerator power supply 134 may be capable of supply a voltage up to 2.5 MV, although other voltages, either higher or lower, are also possible. Thus, to modify the implant energy, the voltage applied by the accelerator power supply 134 is changed.

After exiting the tandem accelerator 130, the positive ion beam 135 may enter a filter magnet 140, which allows passage of ions of only a certain charge. In other embodiments, the filter magnet 140 may not be employed.

The output of the filter magnet, which may be a spot ion beam 155, is then directed toward the spinning disk 300. A workpiece 10 may be disposed on each of the plurality of platens disposed on the spinning disk. In certain embodiments, a corrector magnet may be disposed between the filter magnet 140 and the spinning disk 300.

Additionally, the semiconductor processing apparatus includes a controller 180. The controller 180 may include a processing unit, such as a microcontroller, a personal computer, a special purpose controller, or another suitable processing unit. The controller 180 may also include a non-transitory computer readable storage element, such as a semiconductor memory, a magnetic memory, or another suitable memory. This non-transitory storage element may contain instructions and other data that allows the controller 180 to perform the functions described herein.

The controller 180 may be in communication with the accelerator power supply 134, so as to control the implant energy. In addition, the controller 180 may be in communication with the spinning disk 300 as described in more detail below. The controller 180 may also be in communication with other components.

A second embodiment is shown in FIG. 1B. Components that are common with FIG. 1A are given identical reference designators.

As described above, a semiconductor processing system comprises an ion source 100, which is used to generate an ion beam. The ion source 100 has an aperture through which ions may be extracted from the ion source 100. These ions may be extracted from the ion source 100 by applying a negative voltage to the extraction optics 103 disposed outside the ion source 100, proximate the extraction aperture. The ions may then enter a mass analyzer 120, which may be a magnet that allows ions having a particular mass to charge ratio to pass through. This mass analyzer 120 is used to separate only the desired ions. It is the desired ions that then enter the linear accelerator 200.

The desired ions then enter a buncher 210, which creates groups or bunches of ions that travel together. The buncher 210 may comprise a plurality of drift tubes, wherein at least one of the drift tubes may be supplied with an AC voltage. One or more of the other drift tubes may be grounded. The drift tubes that are supplied with the AC voltage may serve to accelerate and manipulate the ion beam into discrete bunches.

The linear accelerator 200 comprises one or more cavities 201. Each cavity 201 comprises a resonator coil 202 that may be energized by electromagnetic fields created by an excitation coil 205. The excitation coil 205 is disposed in the cavity 201 with a respective resonator coil 202. The excitation coil 205 is energized by an excitation voltage, which may be a RF signal. The excitation voltage may be supplied by a respective RF generator 204. In other words, the excitation voltage applied to each excitation coil 205 may be independent of the excitation voltage supplied to any other excitation coil 205. Each excitation voltage is preferably modulated at the resonance frequency of its respective cavity 201.

When an excitation voltage is applied to the excitation coil 205, a voltage is induced on the resonator coil 202. The result is that the resonator coil 202 in each cavity 201 is driven by a sinusoidal voltage. Each resonator coil 202 may be in electrical communication with a respective accelerator electrode 203. The ions pass through apertures in each accelerator electrode 203.

The entry of the bunch into a particular accelerator electrode 203 is timed such that the potential of the accelerator electrode 203 is negative as the bunch approaches, but switches to positive as the bunch passes through the accelerator electrode 203. In this way, the bunch is accelerated as it enters the accelerator electrode 203 and is repelled as it exits. This results in an acceleration of the bunch. This process is repeated for each accelerator electrode 203 in the linear accelerator 200. Each accelerator electrode 203 increases the acceleration of the ions.

After the bunch exits the linear accelerator 200, the ions, which may be a spot ion beam 155, are directed toward spinning disk 300.

The controller 180 may be in communication with the RF generator 204, so as to control the implant energy. In addition, the controller 180 may be in communication with the spinning disk 300 as described in more detail below. The controller 180 may also be in communication with other components, such as the translating structure 330.

Of course, the ion implantation system may include other components, such as quadrupole elements, additional electrodes to accelerate or decelerate the beam and other elements.

In both of these embodiments, the ion implantation system comprises an ion source, and an accelerator to accelerate the ions.

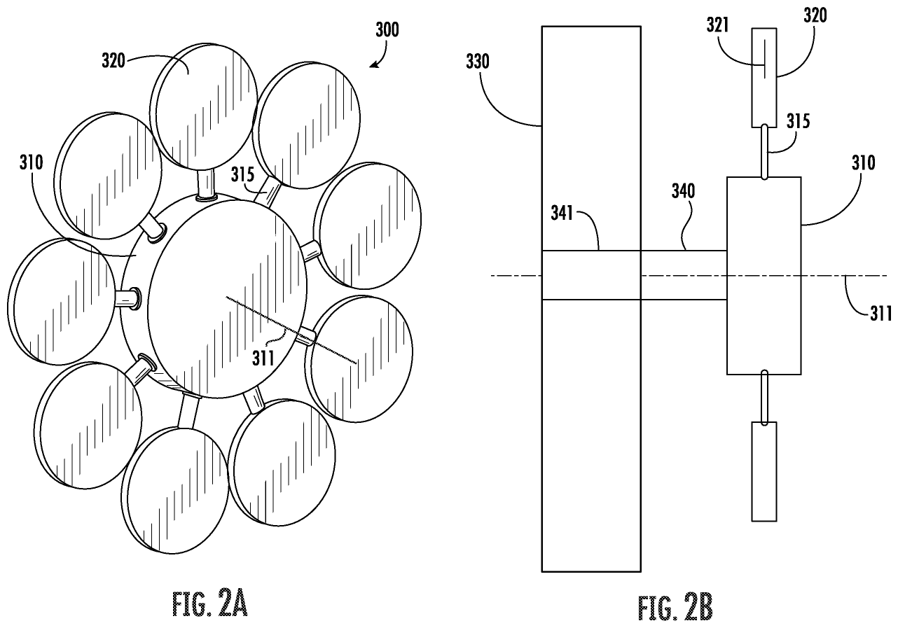

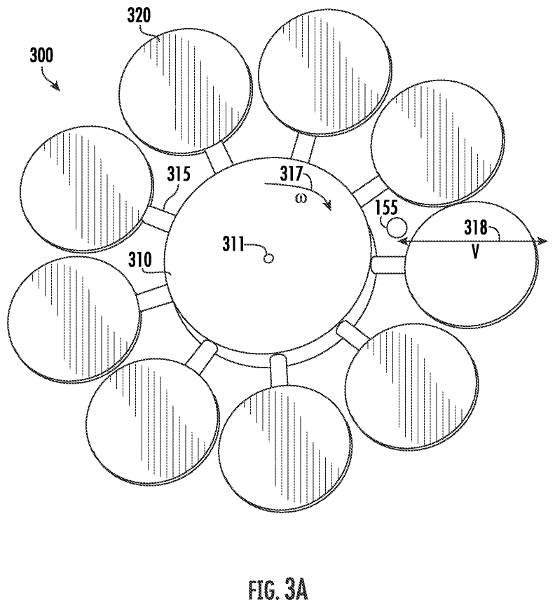

The output from the semiconductor processing system, which may be a spot ion beam 155, is directed toward a spinning disk 300. One embodiment of a spinning disk 300 is shown in FIG. 2A. A side view of this spinning disk is shown in FIG. 2B.

The spinning disk 300 comprises a central hub 310, which rotates about a central axis 311. The spinning disk 300 may be connected to a translating structure 330 using a spindle assembly 340. The spindle assembly is in communication with a rotating motor 341 that allows the spinning disk 300 to rotate about the central axis 311. The rotating motor 341 may be in communication with the controller 180 to control the angular rate.

Extending outward from the central hub 310 are a plurality of spokes 315, each with a respective platen 320 attached to the distal end of the spoke 315. There may be between four and twenty or more platens 320. The platens 320 may be fixedly attached to the spokes 315.

Referring to FIG. 2B, the platens 320 may each utilize electrostatic clamping. The electrostatic clamping may be realized using either AC or DC voltages. In one embodiment, the top surface of the platens may be a dielectric material, such as a ceramic. Beneath the top surface may be a plurality of electrodes 321.

In the case of DC clamping, where may be two electrodes 321, wherein the first electrode is biased at a positive voltage having a predetermined magnitude and the second electrode is biased at a negative voltage having the same magnitude. The electrodes may be suitable shaped. In one embodiment, the two electrodes may be adjacent spirals. The magnitude of the DC voltages may be between 200 and 2000 V.

In the case of AC clamping, there may be an even number of electrodes 321, such as six electrodes. The electrodes 321 may be arranged in opposing pairs, where the phase of the two electrodes of the pair have a phase difference of 180°. Thus, each pair of electrodes may be in electrical communication with a respective bipolar power signal, such as a square wave, such that one electrode of a pair receives the positive output and the other electrode of that pair receives the negative output. The same square wave output, in terms of period and amplitude, is applied to all of the electrodes. However, each square wave output is phase shifted from those adjacent to it. The phase between adjacent electrodes may be equal to 360°/N, where N is the number of electrodes.

In certain embodiments, the frequency of the AC voltage or pulsed DC voltage may be between 1 and 60 Hz, while the amplitude may be between 200 and 4000 V. In certain embodiments, there are 6 electrodes, configured as three pairs. One pair of these electrodes is powered by a first square wave, while a second pair of electrodes is powered by a second square wave, which has a phase shift of 120° relative to the first square wave. Similarly, the third square wave is phase shifted 120° from the second square wave. Of course, other configurations are also within the scope of the disclosure.

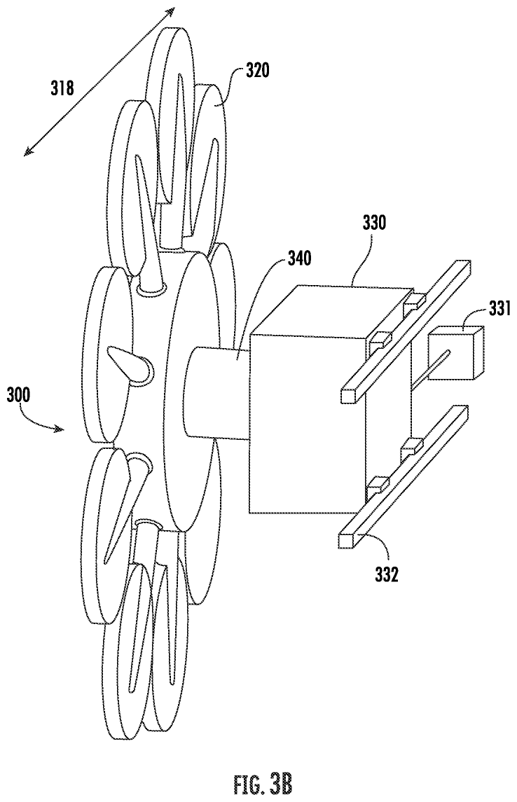

As seen in FIG. 3A, in operation, a spot ion beam 155 is directed toward an area near the spinning disk 300. The central hub 310 rotates along path 317 about central axis 311. In certain embodiments, the maximum speed of rotation, ω, may be between 30 RPM and 1000 RPM. In other embodiments, the speed of rotation, ω, may be 300 RPM or less. As described below, the speed of rotation, ω, may vary as a function of radius. In certain embodiments, the ratio of the maximum speed of rotation to the minimum speed of rotation may be 3. Of course, other rates of rotation and other ratios are also possible. Additionally, the central hub 310 may be translated linearly, such as horizontally along path 318 by moving the translating structure 330. The edge of the platens 320 that is closest to the central hub 310 may be referred to as the inner perimeter of the spinning disk 300, while the edge of the platens that is furthest from the central hub 310 may be referred to as the outer perimeter. These dimensions may be measured from the central axis 311. In other words, the spot ion beam 155 impacts the platens 320 whenever the spot ion beam 155 at a distance from the central axis 311 that is between the radius at the inner perimeter, Rᵢ, and the radius at the outer perimeter, Rₒ.

The maximum linear speed, v, may be between 5 and 50 cm/sec, although other speeds are also possible. As described below, the linear speed, v, may vary as a function of radius. In certain embodiments, the ratio of the maximum linear speed to the minimum linear speed may be 3. Of course, other linear speeds and other ratios are also possible. The path 318 is defined such that at the two ends of the path, the spot ion beam 155 does not strike a platen 320. In other words, at one end of the path 318, the spot ion beam 155 is beyond the outermost edge of the platen 320. Stated differently, the spot ion beam 155 is beyond the outermost edge of the platen 320 occurs whenever the distance from the spot ion beam 155 to the central axis 311 is greater than Rₒ. At the other end of path 318, the spot ion beam 155 is directed to the area between the central hub 310 and the inner edge of the platens 320. This occurs whenever the distance from the spot ion beam 155 to the central axis 311 is less than Rᵢ. Thus, in certain embodiments, the spokes 315 are of a length that is greater than the maximum diameter of the spot ion beam 155 such that there is a position where the spot ion beam 155 is between the central hub 310 and the platens 320. By including spokes 315, the central hub 310 is not impacted by the spot ion beam 155 as the central hub 310 is translated horizontally along path 318. Further, the path 318 may be perpendicular to the rotation of central hub 310 as the platen passes through the spot ion beam 155, resulting in a two dimensional mechanical scanning. At locations between Rᵢ and Rₒ, the spot ion beam 155 strikes the workpieces at a location referred to as the radius of impact.

The translating structure 330 may comprise a carriage that moves along a rod, wherein the carriage holds the spinning disk 300. In other embodiments, shown in FIG. 3B, the translating structure 330 may move along guide rails 332. In this embodiment, the translating structure 330 is supported by guide rails 332 and the actuator 331 drives the translating structure 330 linearly along path 318. This linear direction may be perpendicular to the central axis 311. The actuator 331 may be in communication with the controller 180. The actuator 331 may be any linear actuation device including ball screws and linear motors. In certain embodiments, the actuator and translation mechanism may be positioned outside of the vacuum process chamber and vacuum seals may be used to isolate the mechanism from the process environment. In another embodiment, the translating structure 330 could also be supported by a cylindrical rod or other type of linear bearing. The rotating motor 341 is located within the translating structure 330.

In certain embodiments, the scan velocity, v, varies inversely as the radius of impact, which is the radius of the spinning disk 300, as measured from the central axis 311, that is being impacted by the spot ion beam 155. In other words, when the translating structure 330 is positioned such that the outer edge of the platens 320 are being impacted by the spot ion beam 155, (i.e., the radius of impact is Rₒ) the translating structure 330 is moving slower than when the translating structure 330 is positioned such that the inner edge of the platens 320 are being impacted by the spot ion beam 155 (i.e., the radius of impact is Rᵢ). In this way, the dose is more uniform. Specifically, at high rotation rates, ω, the dose delivered in one pass as the translating structure 330 moves between its two limits can be expressed as:

$$D ( r ) = {\int }_{{R}_{i}}^{{R}_{o}} \frac{I}{2 π rv ( t )} dt ,$$

where I is the beam current, in ions/second; r is the radius of impact in centimeters, v(t) is the scan velocity in cm/s and D(r) is the dose delivered as a function of radius, expressed in ions/cm².

Notably, if the scan velocity, v, is defined as:

$$v = \frac{I}{{D}_{p} 2 π r} ,$$

where Dp is the dose per pass, then it can be seen that D(r) is given by

$$v = \frac{dR}{dt} = \frac{I}{{D}_{p} 2 π r} , or dt = \frac{{D}_{p} 2 π r}{I} dR$$

so that

$$D ( r ) = {\int }_{{R}_{i}}^{{R}_{o}} \frac{I}{2 π rv ( t )} dt = {\int }_{{R}_{i}}^{{R}_{o}} \frac{I}{2 π r} \frac{{D}_{p} 2 π r}{I} dR = {D}_{p}$$

for Rᵢ<R<Rₒ
and is a constant, Dp. It is only strictly true for a point beam, and actual beams with significant extent may need small corrections from this to achieve optimum uniformity.

Thus, to achieve this result, the controller 180 monitors the position of the translating structure 330 and adjusts the scan velocity of the translating structure 330 based on its position. In this disclosure, the position of the translating structure 330 refers to the distance between the central axis 311 and the spot ion beam 155, which is also defined as the radius of impact. Since the spot ion beam 155 is stationary, the position of the translating structure 330, and consequently the radius of impact, is changed by actuator 331. In some embodiments, the translating structure 330 includes one or more encoders or proximity sensors that allow the controller 180 to monitor the actual position of the translating structure 330. In other embodiments, the controller 180 may know the position of the translating structure based solely on time. In certain embodiments, the controller may include a table or equation that determines the scan velocity and/or the rotation rate based on time. The controller 180 provides velocity information to the actuator 331 based on the position of the translating structure 330. In one embodiment, the velocity information may comprise the magnitude of the voltage or current supplied to the actuator 331. In another embodiment, the controller 180 may provide commands to the actuator 331, such as through the use of a wired or wireless protocol. The actuator 331 then converts these commands into a speed. In this way, the translating structure 330 moves at a speed that is inversely proportional to the radius of the spinning disk 300 that is being impacted by the spot ion beam 155, also referred to as the radius of impact. The maximum linear speed may be selected based on optimal productivity.

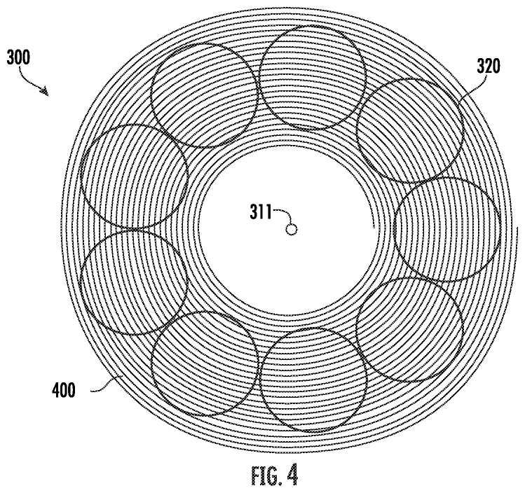

Advantageously, in certain embodiments, the rotation rate, ω, is decreased as the radius increases. In certain embodiments, the rotation rate varies inversely as the radius of impact. In other words, when the spot ion beam 155 is directed at the outer perimeter of the spinning disk 300, (i.e., the radius of impact is Rₒ), the spinning disk 300 will rotate faster than when the spot ion beam 155 is directed at the inner perimeter of the spinning disk 300 (i.e., the radius of impact is Rᵢ). This approach provides a uniform spacing of the lines drawn by the center of beam as illustrated in FIG. 4. The spacing of the lines is given by

$$Δ R = 2 π \frac{v}{ω}$$

and, since

$$v ∝ \frac{1}{r}$$

to achieve dose uniformity, ω may be similarly controlled to achieve uniform spacing. Thus, in some embodiments, the rotation rate and the scan velocity are varied as a function of radius such that the ratio or scan velocity to rotation rate remains nearly constant. In this disclosure, “nearly constant” is defined such that the ratio changes by less than 20%. In some embodiments, the ratio may change by less than 10%.

In one embodiment, the rotation rate, ω, is defined as a constant divided by the radius of impact. This constant may be determined based on the highest desirable rotation rate. The maximum desirable rotation rate may be selected based on optimal productivity. The controller 180 may obtain or calculate the current position of the translating structure, and therefore, the radius of impact, and provide rotational information to the rotating motor 341. The current position of the translating structure 330 may be obtained using the techniques described above. The rotational information may be provided to the rotating motor 341 as a voltage, a current or a digital command.

FIG. 4 shows the path 400 of a spot ion beam 155 across the spinning disk 300 which is moving at a varying scan velocity, v, and a varying rotation rate, ω. The path 400 is a spiral where the spacing between adjacent convolutions of the spiral is nearly constant through the entirety of the implant.

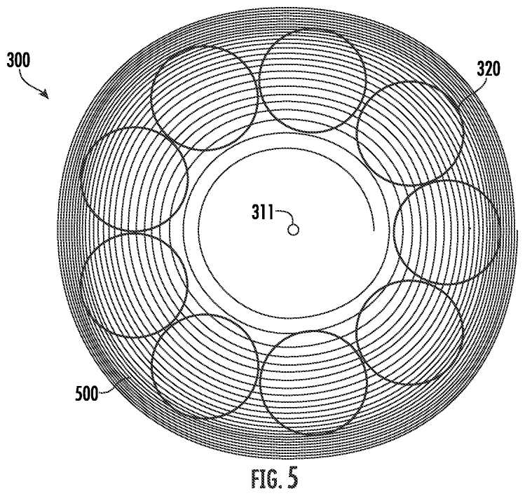

The system and method described herein have many advantages. As seen in FIG. 4, the spacing between adjacent convolutions of the spiral is nearly constant. In contrast, an implant that is performed using a variable scan velocity and a constant rotation rate yields the path 500 shown in FIG. 5. Note that the spacing between convolutions is greater near the inner diameter of the spinning disk 300.

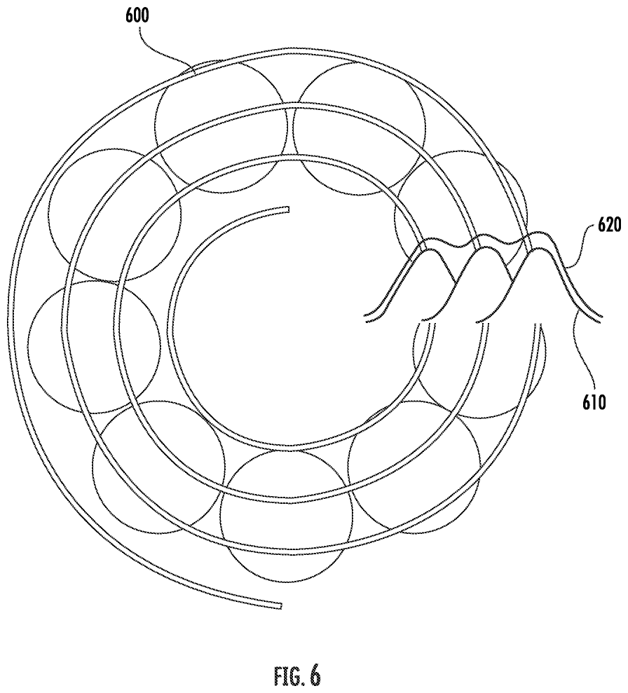

Thus, due to greater spacing, it is possible to incur microuniformity issues. FIG. 6 shows a simplified figure showing the effects of slow rotation rate, combined with a varying scan velocity. Spiral 600 shows the path of the spot ion beam 155. Curves 610 show the dose implanted by the spot ion beam 155 at various points during the rotation of the spinning disk 300. Note that the dose is greatest on the spiral 600 and decreases on either side of the spiral 600. Curve 620 shows the cumulative dose that is obtained by adding the dose contributed by the spot ion beam 155 during all convolutions. Note that the dose between convolutions of the spiral 600 is less than the dose on the spiral 600. This microuniformity may be problematic if the difference between the maximum dose and minimum dose is too great. By varying the rotation rate, ω, inversely with radius of impact, the spacing between convolutions remains more constant, which reduces microuniformity.

Additionally, using a variable scan velocity and variable rotation rate, the instantaneous dose rate history of each point on the workpiece is much more constant. Specifically, with respect to the implant shown in FIG. 5, the points near the inner radius are moving at a slower speed and therefore will spend more time exposed to the spot ion beam 155. It has been found that defect accumulation in single crystal silicon can be very sensitive to the instantaneous dose rate history and may cause device performance variation between the inner radius and the outer radius. Using the variable rotation rate described herein may make this instantaneous dose rate history more uniform across the entirety of the workpieces.

Thus, in summary, the use of variable scan velocity and variable rotation rate may result in more uniform dose, more uniform spacing between convolutions of the spiral, and a more uniform instantaneous dose rate time signature for each point on the workpieces.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A batch implanter, comprising:
a spinning disk adapted to process a plurality of workpieces, comprising:
a central hub adapted to rotate about a central axis;
a plurality of spokes extending radially outward from the central hub;
a platen disposed on a distal end of each of the plurality of spokes; and
a translating structure on which the spinning disk is mounted, wherein a spot ion beam is adapted to strike the spinning disk at a distance from the central axis, referred to as a radius of impact, and wherein a rotation rate of the spinning disk about the central axis decreases as the radius of impact increases.

2. The batch implanter of claim 1, wherein the rotation rate varies inversely as the radius of impact.

3. The batch implanter of claim 1, wherein a maximum rotation rate of the spinning disk is between 30 and 1000 RPM.

4. The batch implanter of claim 1, wherein the translating structure moves at a scan velocity, and the scan velocity decreases as the radius of impact increases.

5. The batch implanter of claim 4, wherein the scan velocity varies inversely as the radius of impact.

6. The batch implanter of claim 4, where a maximum scan velocity is between 5 and 50 cm/sec.

7. An ion implantation system, comprising:
an ion source to generate ions;
an accelerator to accelerate the ions and create a spot beam; and
the batch implanter of claim 1.

8. A batch implanter, comprising:
a spinning disk adapted to process a plurality of workpieces, comprising a plurality of platens and a rotating motor to rotate the spinning disk about a central axis;
a translating structure on which the spinning disk is mounted, wherein a spot ion beam is adapted to strike the spinning disk at a distance from the central axis, referred to as a radius of impact;
an actuator configured to move the translating structure linearly at a scan velocity; and
a controller, in communication with the rotating motor wherein the controller controls the rotating motor such that a rotation rate of the spinning disk about the central axis decreases as the radius of impact increases.

9. The batch implanter of claim 8, wherein the controller controls the rotating motor such that the rotation rate varies inversely as the radius of impact.

10. The batch implanter of claim 9, wherein a maximum rotation rate of the spinning disk is between 30 and 1000 RPM.

11. The batch implanter of claim 8, wherein the controller is in communication with the actuator and controls the actuator such that the scan velocity of the translating structure decreases as the radius of impact increases.

12. The batch implanter of claim 11, wherein the scan velocity varies inversely with the radius of impact.

13. The batch implanter of claim 11, wherein the translating structure moves linearly in a direction perpendicular to the central axis.

14. The batch implanter of claim 8, further comprising one or more sensors in communication with the controller, wherein the controller determines the radius of impact based on information from the one or more sensors.

15. The batch implanter of claim 8, wherein the controller determines the radius of impact using a table or equation based on time.

16. An ion implantation system, comprising:
an ion source to generate ions;
an accelerator to accelerate the ions and create a spot beam; and
the batch implanter of claim 8.

17. A batch implanter, comprising:
a spinning disk adapted to process a plurality of workpieces, comprising a plurality of platens and a rotating motor to rotate the spinning disk about a central axis; and
a translating structure on which the spinning disk is mounted, wherein the translating structure is configured to move at a scan velocity; wherein a spot ion beam is adapted to strike the spinning disk at a distance from the central axis, referred to as a radius of impact, and wherein a rotation rate of the spinning disk and the scan velocity vary as a function of the radius of impact, and wherein a ratio of the scan velocity to the rotation rate remains nearly constant as the translating structure moves.

18. The batch implanter of claim 17, wherein the scan velocity and the rotation rate vary inversely with the radius of impact.

19. An ion implantation system, comprising:
an ion source to generate ions;
an accelerator to accelerate the ions and create a spot beam; and
the batch implanter of claim 17.
